(19) United States
(12) Patent Application Publication
(10) Pub. No.: US 2026/0298756 A1
(43) Pub. Date: Oct. 1, 2026

(54) SELF-DIAGNOSIS APPARATUS FOR PIEZOELECTRIC FILM SENSORS

(71) Applicant: INTERLINK ELECTRONICS, INC., Fremont, CA (US)

(72) Inventors: Zhiyun CHEN, Irvine, CA (US); Yen Ching LIM, Irvine, CA (US); Kyung Tae PARK, Irvine, CA (US)

(73) Assignee: INTERLINK ELECTRONICS, INC., Fremont, CA (US)

(21) Appl. No.: 19/477,427

(22) PCT Filed: Apr. 21, 2023
(86) PCT No.: PCT/US2023/019471

§ 371 Date: Oct. 21, 2025

(51) Int. Cl. G01L 25/00; G01L 1/16

(52) U.S. Cl. CPC G01L 25/00; G01L 1/16

(57) ABSTRACT

In an example, a system may include a first piezo film sensor and a second piezo film sensor. The first piezo film sensor may be coupled to a sensing object. The first piezo film sensor may have a first reference capacitance and a first measured capacitance and may be configured to emit a drive signal. The second piezo film sensor may be coupled to the sensing object. The second piezo film sensor may have a second reference capacitance and a second measured capacitance. The second piezo film sensor may receive the drive signal and generate an output based on the drive signal. A first operational status associated with the first piezo film sensor and a second operational status associated with the second piezo film sensor may be determined using the first reference capacitance, the first measured capacitance, the second reference capacitance, the second measured capacitance, and the output.

### FIELD

The embodiments discussed in the present disclosure are related to a self-diagnosis apparatus and a self-diagnosis process for piezoelectric film sensors.

### BACKGROUND

Physical sensors may be used to monitor safety and/or performance of various devices. For those sensor applications where safety may be critically important, self-monitoring the health status and/or functionality of the physical sensor itself may be desirable. Depending on various physical sensor types, operating principles may vary such that self-diagnosis methods for the various physical sensor types may be unique.

Piezoelectric polymer may be a light weight, flexible, and robust polymer sensing material which can be used as a dynamic strain sensor. The size and shape of the piezoelectric polymer can be easily customized for various applications. Unlike the traditional piezoelectric materials, which may include ceramics, crystals, semiconductor strain sensors, or foil strain sensors, piezoelectric polymer, which may include soft piezo film sensors can be used for applications having wide sensing coverage areas and/or curved sensing surfaces. In some circumstances, using the piezoelectric polymer as a strain sensor, the piezoelectric polymer may be laminated and/or bonded on one or more surfaces of a sensing object.

The subject matter claimed herein is not limited to embodiments that solve any disadvantages or that operate only in environments such as those described above. Rather, this background is only provided to illustrate one example technology area where some embodiments described herein may be practiced.

### SUMMARY

According to an aspect of an embodiment, a system may include a first piezo film sensor and a second piezo film sensor. The first piezo film sensor may be coupled to a sensing object. The first piezo film sensor may have a first reference capacitance and a first measured capacitance and may be configured to emit a drive signal. The second piezo film sensor may be coupled to the sensing object. The second piezo film sensor may have a second reference capacitance and a second measured capacitance. The second piezo film sensor may be configured to receive the drive signal and generate an output based on the drive signal. A first operational status associated with the first piezo film sensor and a second operational status associated with the second piezo film sensor may be determined using the first reference capacitance, the first measured capacitance, the second reference capacitance, the second measured capacitance, and the output.

The object and advantages of the embodiments will be realized and achieved at least by the elements, features, and combinations particularly pointed out in the claims.

Both the foregoing general description and the following detailed description are given as examples and are explanatory and are not restrictive of the invention, as claimed.

### BRIEF DESCRIPTION OF THE DRAWINGS

Example embodiments will be described and explained with additional specificity and detail through the use of the accompanying drawings in which:

FIG. 1 illustrates an example configuration of a piezo film sensor;

FIG. 2 illustrates an example piezo film sensor and related anisotropic sensitivity;

FIG. 3 illustrates an example voltage mode equivalent circuit of a piezo film sensor;

FIG. 4 is a graph illustrating a relationship between temperature and capacitance of a piezo film sensor;

FIG. 5 is a graph illustrating a relationship between temperature and sensitivity of a piezo film sensor;

FIG. 6A illustrates an example embodiment of a self-diagnosis apparatus including a piezo film sensor;

FIG. 6B illustrates an example piezo film that may be used in the self-diagnosis apparatus of FIG. 6A;

FIG. 7 illustrates an example embodiment of a self-diagnosis apparatus including two piezo film sensors;

FIG. 8A illustrates an example embodiment of a self-diagnosis apparatus including a piezo film sensor;

FIG. 8B illustrates an example piezo film sensor that may be used in the self-diagnosis apparatus of FIG. 8A;

FIG. 9 illustrates a flowchart of a self-diagnosis process for a piezo film sensor; and

FIG. 10 illustrates a flowchart of an example method of a self-diagnosis process for a piezo film sensor.

### DETAILED DESCRIPTION OF EMBODIMENTS

Piezoelectric polymer such as polyvinylidene fluoride (PVDF), also known as (VF2), or copolymer, also known as polyvinylidene fluorine-trifluoroethylene (VF2VF3) may be a thin (e.g., 2 μm to 200 μm thick), light weight, flexible, and/or robust polymer sensing material which can be used as a dynamic strain sensor. In the present disclosure, “piezo film” and/or “piezo film sensor” may be used to include piezoelectric PVDF and/or copolymers for convenience. A piezo film sensor size and/or piezo film sensor shape may be tailored to various applications using a piezo film sensor.

In some circumstances, a piezo film sensor may be a polymer-based strain sensor, such as the piezoelectric polymer. The piezo film sensor may generate an electrical charge or a voltage without an external power supply when a mechanical stress and/or strain is applied. In some circumstances, the output from a piezo film sensor may be linearly proportional to the applied stress and/or strain to the piezo film sensor. The piezo film sensor may generate a positive going signal when the piezo film sensor is stretched and a negative going signal when the piezo film sensor is compressed, or vice versa depending on an associated interface circuit arrangement.

As the piezo film sensor is a polymer-based strain senor, the sensitivity (piezoelectric stress and/or strain constants) and capacitance of the piezo film sensor may be temperature dependent. Therefore, in order to monitor an operational status associated with a piezo film sensor, an environmental temperature where the piezo film sensor may be installed may be considered in addition to or in the alternative to a remote location associated with other electronics. In some circumstances, the consideration of the environmental temperature may introduce a prominent effect on the piezo film sensor, such as various outdoor applications, where variations in environmental temperatures may be more prominent relative to various indoor applications.

In some embodiments, determining an operational status of a piezo film sensor may include determining if the piezo film sensor may be physically damaged, which may include a short circuit, an open circuit (e.g., broken wires), cut piezo film, and/or delaminated electrodes. Alternatively, or additionally, the operational status may include determining if the sensitivity of the piezo film sensor is reduced or dead. The sensitivity of the piezo film sensor can be permanently damaged if exposed to an elevated temperature for an extended period, such as greater than 125° C. over 2 or more hours. Alternatively, or additionally, the operational status may include determining if the piezo film sensor may be delaminated from a surface of the sensing object.

In the present disclosure, various self-diagnosis embodiments using piezo film sensors are disclosed. Each of the piezo film sensor embodiments can monitor an operational status and/or the sensitivity of the included piezo film sensors without using additional temperature sensors.

Embodiments of the present disclosure will be explained with reference to the accompanying drawings.

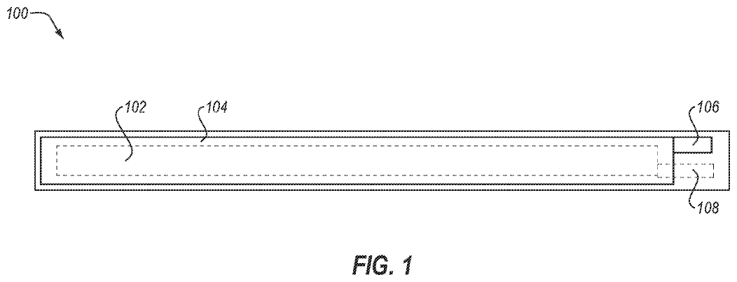

FIG. 1 illustrates an example configuration of a piezo film sensor 100, in accordance with at least one embodiment of the present disclosure. In some embodiments, the piezo film sensor 100 may include a positive electrode 102, a negative electrode 104, a ground terminal 106, and a signal terminal 108.

In some embodiments, the ground terminal 106 may be coupled to a ground wire and/or may be configured to receive and/or transmit a grounding signal. Alternatively, or additionally, the signal terminal 108 may be coupled to a signal wire and/or may be configured to receive and/or transmit a signal, such as a drive signal as described herein. In some embodiments, the ground terminal 106 may be coupled to the negative electrode 104 and the signal terminal 108 may be coupled to the positive electrode 102. Alternatively, or additionally, the ground terminal 106 may be coupled to the positive electrode 102 and the signal terminal 108 may be coupled to the negative electrode 104, which may invert an output from the piezo film sensor 100. For example, in response to receiving a particular strain input, the piezo film sensor 100 may generate a positive going signal under the first configuration and the piezo film sensor 100 may generate a negative going signal under the second configuration.

In some embodiments, the piezo film sensor 100 and/or any of the embodiments of the piezo film sensor included in the present disclosure may include some or all of the following characteristics. The piezo film sensor 100 may be between 5 um and 250 um in thickness. The piezo film sensor 100 may be polarized such that one side of the piezo film sensor 100 may be a positive polarity and the other side of the piezo film sensor 100 may be a negative polarity. The piezo film sensor 100 may have the positive electrode 102 disposed on a first side and the negative electrode 104 disposed on a second side thereof. The positive electrode 102 and/or the negative electrode 104 may be a printed silver ink or a carbon ink. Alternatively, or additionally, the positive electrode 102 and/or the negative electrode 104 may be a sputtered electrode such as gold (Au), silver (Ag), aluminum (Al), copper (Cu), or indium tin oxide (ITO). In some embodiments, the negative electrode 104 may be larger than the positive electrode 102. The piezo film sensor 100 may be laminated on one side or both sides using a thin plastic film, such as 125 um thick or thinner polyethylene terephthalate (PET) film, where the lamination may provide protection to the piezo film sensor 100 from the environment and/or handling. Alternatively, or additionally, the piezo film sensor 100 may be used without lamination.

In instances in which the piezo film sensor 100 is in an actuator mode (e.g., as an emitter), a length of the piezo film sensor 100 may vary (ΔL) by stretching and/or contracting depending on the applied voltage polarity. The length variation of the piezo film sensor 100 may be proportional to the applied voltage amplitude. In instances in which a high frequency drive signal (such as an ultrasound signal) is applied to the piezo film sensor 100, the piezo film sensor 100 may transmit an acoustic wave through the sensing object perpendicularly to the surface of the piezo film sensor 100. In some embodiments, a maximum efficiency can be achieved when a frequency of the drive signal matches a resonance frequency of the piezo film sensor 100. The resonance frequency of a piezo film sensor 100 may be inversely proportional to a thickness of the piezo film sensor 100.

In instances in which the piezo film sensor 100 is in a sensing mode (e.g., as a receiver), the piezo film sensor 100 may generate a positive going signal when the piezo film sensor 100 is stretched and may generate a negative going signal when the piezo film sensor 100 is contracted, or vice versa, depending on the interface electronics arrangement. In some embodiments, an amplitude of the generated signal may be proportional to the applied stress or strain to the piezo film sensor 100.

In an example, a first piezo film sensor (e.g., the piezo film sensor 100) may be coupled to a sensing object and the first piezo film sensor may be configured to emit a drive signal. Alternatively, or additionally, the first piezo film sensor may have a first parameter associated therewith. The first parameter may include a first reference capacitance and/or a first measured capacitance individually associated with the first piezo film sensor.

In some embodiments, a second piezo film sensor (e.g., the piezo film sensor 100) may be coupled to the sensing object and the second piezo film sensor may be configured to receive the drive signal and generate an output in response to the drive signal. Alternatively, or additionally, the second piezo film sensor may have a second parameter associated therewith. The second parameter may include a second reference capacitance and/or a second measured capacitance individually associated with the first piezo film sensor.

In some embodiments, a first operational status associated with the first piezo film sensor and/or a second operational status associated with the second piezo film sensor may be determined using the first parameter, the second parameter, and the output from the second piezo film sensor.

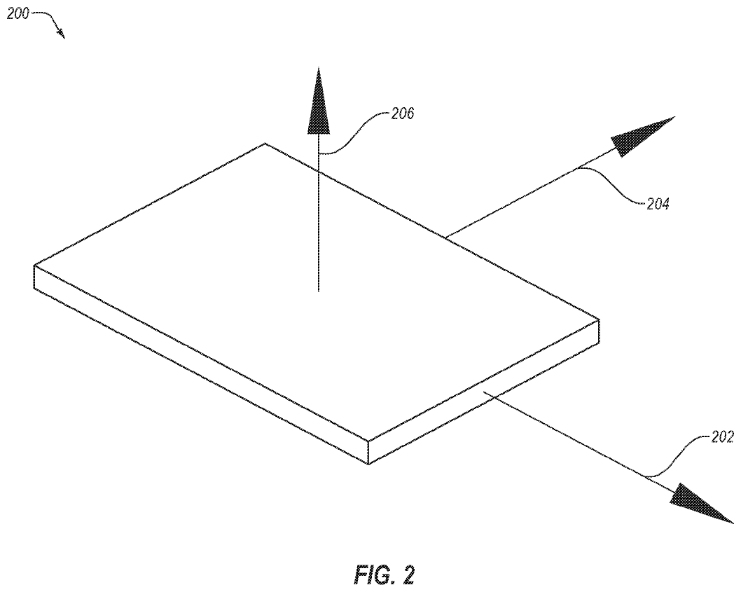

FIG. 2 illustrates an example piezo film sensor 200 and related anisotropic sensitivity, in accordance with at least one embodiment of the present disclosure. In some embodiments, the piezo film sensor 200 may include a longitudinal direction 202, a transverse direction 204, and a thickness direction 206.

In some embodiments, a sensitivity in the longitudinal direction 202 of the piezo film sensor 200 (e.g., a stress constant of approximately 220×10-3 Vm/N and/or a strain constant of approximately 25 pC/N) may be higher than a sensitivity in the transverse direction 204 (e.g., a stress constant of approximately 20×10-3 Vm/N and/or a strain constant of approximately 2 pC/N). As such, in some embodiments, a piezo film sensor may have a longitudinally extended configuration where the longitudinal direction 202 may be longer than the transverse direction 204, such as shown by the piezo film sensor 100 of FIG. 1. A longitudinally extended configuration may be advantageous when an area associated with a sensing object may be wide and/or long. In some embodiments, the piezo film sensor 200 may be coupled (e.g., bonded or adhered) on a surface of the sensing object, and the piezo film sensor 200 may be used as a dynamic strain sensor. In some embodiments, the sensing object may be a part of the self-diagnosis apparatus.

In some embodiments, the thickness direction 206 may be associated with a thickness of the piezo film sensor 200. In some embodiments, a resonance frequency of a piezo film sensor 200 may be inversely proportional to a thickness of the piezo film sensor 200.

In these or other embodiments, the longitudinal direction 202, the transverse direction 204 and/or the thickness direction 206 may individually include a stress constant and/or a strain constant that may indicate a sensitivity to an applied stress and/or strain to the piezo film sensor 200.

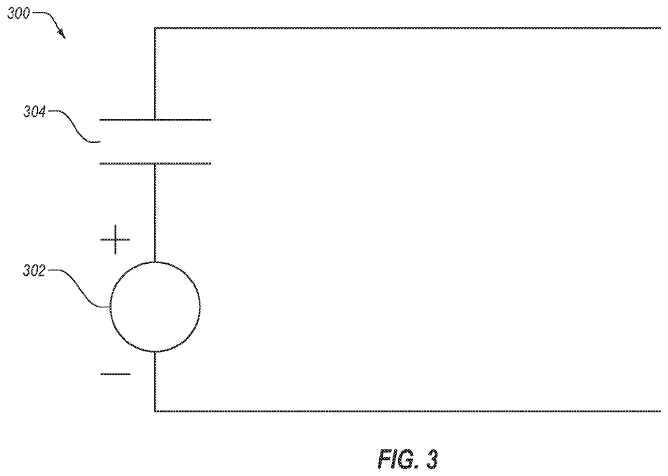

FIG. 3 illustrates an example voltage mode equivalent circuit 300 of a piezo film sensor, in accordance with at least one embodiment of the present disclosure. In some embodiments, the voltage mode equivalent circuit 300 may include an internal voltage generator 302 and an internal capacitance 304.

In some embodiments, the internal voltage generator 302 of the voltage mode equivalent circuit 300 may generate a generated voltage that may include accumulated electric charge in response to an applied mechanical stress to the piezo film sensor, such as the piezo film sensor 100 of FIG. 1. The generated voltage by the internal voltage generator 302 may be proportional to an applied stress and/or strain to the piezo film sensor. In some embodiments, the internal capacitance 304 may be in series relative to the internal voltage generator 302. The internal capacitance 304 may be proportional to an active area of the piezo film sensor (e.g., electrode areas of the piezo film sensor, such as illustrated relative to FIG. 1 herein) and may be inversely proportional to a thickness of the piezo film sensor. Therefore, by measuring the internal capacitance 304 of the piezo film sensor, an operational status of the piezo film sensor may be determined, which may indicate one or more issues with the piezo film sensor, such as one or more broken leads and/or damaged piezo film sensor electrodes, as described herein.

In some embodiments, the piezo film sensor may generate an output that may be proportional to a sensitivity of the piezo film sensor (e.g., a stress constant in the longitudinal direction thereof, such as the longitudinal direction 202 of FIG. 2). In some embodiments, a capacitance of a piezo film sensor may be proportional to an active electrode area of the piezo film sensor (e.g., an overlapped electrode area between a positive electrode and a negative electrode of the piezo film sensor, such as the positive electrode 102 and the negative electrode 104 of FIG. 1), as described relative to FIG. 1.

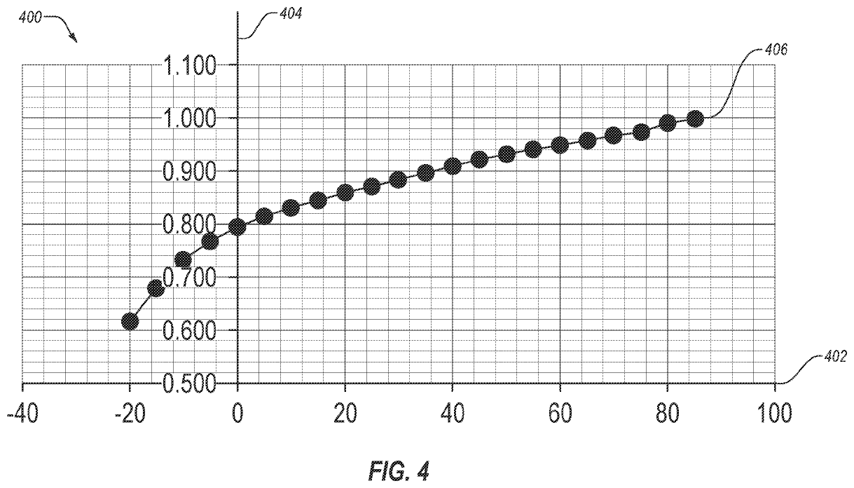

FIG. 4 is a graph 400 illustrating a relationship between temperature and capacitance of a piezo film sensor, in accordance with at least one embodiment of the present disclosure. In some embodiments, the graph 400 may include a temperature axis 402, a capacitance axis 404, and a curve 406.

In some embodiments, as a piezo film sensor may be a soft material, the capacitance of the piezo film sensor may be temperature dependent, such as shown in the graph 400. As such, a measurement of the capacitance of the piezo film sensor may, by itself, be unable to support distinguishing between a damaged piezo film sensor (e.g., where the capacitance of the piezo film sensor may change) and an environmental temperature change (e.g., which may cause the capacitance of the piezo film sensor to change). Hence, in some embodiments, a method of self-diagnosis by the piezo film sensor, which may include monitoring the operational status of the piezo film sensor, may be implemented. Alternatively, or additionally, implementation of a method of self-diagnosis by the piezo film sensor may be beneficial in instances in which the piezo film sensor may be a long strip, such as in an outdoor application, such as instances in which the piezo film sensor may be approximately 1 m long, 25 mm wide in an automotive bumper application as an impact detector.

In some embodiments, capacitance of a piezo film sensor may decrease in instances in which a portion of the piezo film sensor electrode becomes damaged and/or if the piezo film sensor becomes partially, substantially, or fully cut. Alternatively, or additionally, capacitance of the piezo film sensor may be changed due to a change in an environmental temperature associated with the piezo film sensor. For example, in instances in which the environmental temperature decreases, the capacitance may be reduced.

As shown in the graph 400, the curve 406 illustrates how a capacitance (e.g., the capacitance axis 404) associated with a piezo film sensor may vary relative to changes in the environmental temperature (e.g., the temperature axis 402). In some embodiments, at least some portions of the curve 406 may be substantially linear. For example, the curve 406 may be substantially linear between approximately 20° C. and 80° C. on the temperature axis 402, which may indicate an approximately linear relationship between the capacitance and the environmental temperature of the piezo film sensor between approximately 20° C. and 80° C. Alternatively, or additionally, at least some portions of the curve 406 may be substantially nonlinear. For example, the curve 406 may be substantially nonlinear between approximately 20° C. and −20° C. on the temperature axis 402, which may indicate a nonlinear relationship between the capacitance and the environmental temperature of the piezo film sensor between approximately 20° C. and 80° C.

In some embodiments, the capacitance of a piezo film sensor may be utilized to estimate the environmental temperature. For example, a particular piezo film may have known capacitance values for a given temperature, and in instances in which the capacitance of the particular piezo film is measured, the corresponding environmental temperature may be determined.

In an example, the capacitance of a piezo film sensor that is 25 mm long, 13 mm wide, and 30 μm thick may decrease from approximately 0.87 nF at room temperature to approximately 0.61 nF at −20° C., which may be equivalent to approximately a 30% capacitance reduction. Therefore, in some embodiments, it may be difficult and/or not possible to distinguish between the partially damaged piezo film sensor and environmental temperature drop using a measurement of the capacitance of the piezo film sensor. As such, a new method of determining the operational status of a piezo film sensor becomes beneficial, as described herein. An example of the relationship between temperature and capacitance for the above example is provided in the table below:

| | Capacitance of a piezo | |
|---|---|---|
| | film sensor (25 mm | Changes |
| Temperature | long, 13 mm wide, | to 25° C. |
| (° C.) | 30 μm thick) (nF) | (%) |
| −20 | 0.615 | −29.3% |
| −15 | 0.678 | −22.1% |
| −10 | 0.731 | −15.9% |
| −5 | 0.767 | −11.9% |
| 0 | 0.793 | −8.8% |
| 5 | 0.814 | −6.4% |
| 10 | 0.830 | −4.6% |
| 15 | 0.844 | −2.9% |
| 20 | 0.860 | −1.2% |
| 25 | 0.871 | 0.0% |
| 30 | 0.884 | 1.6% |
| 35 | 0.897 | 3.1% |
| 40 | 0.910 | 4.5% |
| 45 | 0.921 | 5.9% |
| 50 | 0.932 | 7.1% |
| 55 | 0.941 | 8.2% |
| 60 | 0.950 | 9.1% |
| 65 | 0.959 | 10.2% |
| 70 | 0.967 | 11.2% |
| 75 | 0.974 | 12.0% |
| 80 | 0.991 | 13.9% |
| 85 | 0.998 | 14.8% |

In some embodiments, the operational status of the piezo film sensor may be diagnosed by testing a measured capacitance (e.g., a capacitance test) and an output/sensitivity (e.g., a sensitivity test) as listed in the following table and described in the present disclosure:

| Operational status of the piezo film sensor | Test method |
|---|---|
| Broken wires (e.g., open circuit), a short circuit, | Capacitance test |
| damaged electrodes, and/or partially cut piezo film | |
| sensor | |
| Reduced and/or dead sensitivity | Sensitivity test |
| Piezo film sensor may not be damaged (thus, no | Sensitivity test |
| capacitance changes) but the piezo film sensor may | |
| be delaminated (e.g., decoupled) from a surface of | |
| the sensing object. | |

In some embodiments, due to the nonlinearity between the capacitance of the piezo film sensor relative to the environmental temperature, a customized lookup table may be used in compensation for the environmental temperature. In some embodiments, contents of the lookup table may vary depending on a variation of the self-diagnosis apparatus.

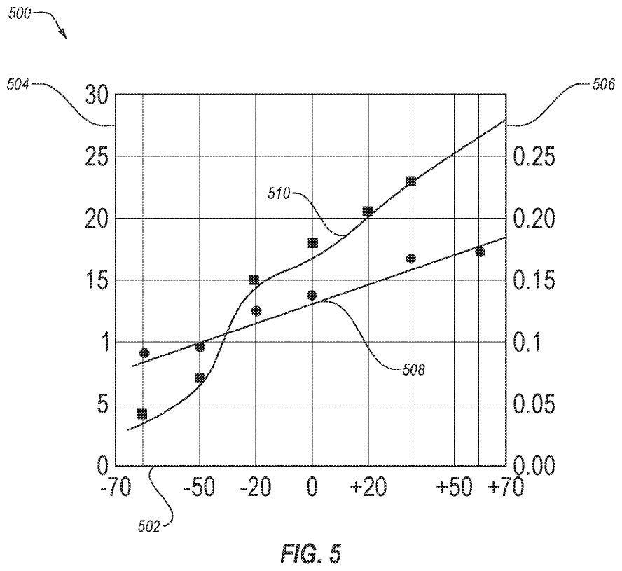

FIG. 5 is a graph 500 illustrating a relationship between temperature and sensitivity of a piezo film sensor, in accordance with at least one embodiment of the present disclosure. In some embodiments, the graph 500 may include a temperature axis 502, a strain constant axis 504, a stress constant axis 506, a strain curve 508, and a stress curve 510.

In some embodiments, the sensitivity (e.g., strain constants represented on the strain constant axis 504 and/or stress constants represented on the stress constant axis 506) of the piezo film sensor may be temperature dependent. For example, the strain constant and/or the stress constant may increase in conjunction with an increase in the environmental temperature, as shown by the strain curve 508 and the stress curve 510. In instances in which the environmental temperature increases, verifying a temperature dependency between the environmental temperature and the sensitivity of the piezo film sensor may be performed, which may contribute to determining the operational status of the piezo film sensor. As such, detecting the environmental temperature associated with the piezo film sensor may be used to compensate for environmental temperature variations that may alter the sensitivity of the piezo film sensor. For some piezo film sensor applications, including wide area sensing applications and/or curved sensing objects, traditional temperature sensors may be limited in applicability as the traditional sensors.

As shown in the graph 500, the strain curve 508 and/or the stress curve 510 illustrates how the sensitivity (e.g., the strain constant axis 504 and/or the stress constant axis 506) associated with the piezo film sensor may vary relative to changes in temperature (e.g., the temperature axis 502). In some embodiments, at least some portions of the stress curve 510 may be substantially linear. For example, the stress curve 510 may be substantially linear between approximately −70° C. and 70° C. on the temperature axis 502, which may indicate an approximately linear relationship between the stress constant and temperature of the piezo film sensor between approximately −70° C. and 70° C.

In some embodiments, at least some portions of the strain curve 508 may be substantially linear. For example, the strain curve 508 may be substantially linear between approximately −20° C. and 50° C. on the temperature axis 502, which may indicate an approximately linear relationship between the strain constant and temperature of the piezo film sensor between approximately −20° C. and 50° C. Alternatively, or additionally, at least some portions of the strain curve 508 may be substantially nonlinear. For example, the strain curve 508 may be substantially nonlinear between approximately −70° C. and −20° C. on the temperature axis 502, which may indicate a nonlinear relationship between the strain constant and the environmental temperature of the piezo film sensor between approximately −70° C. and −20° C.

In some embodiments, due to the nonlinearity between the sensitivity of the piezo film sensor relative to the environmental temperature, a customized lookup table may be used in compensation for the environmental temperature. In some embodiments, contents of the lookup table may vary depending on a variation of the self-diagnosis apparatus.

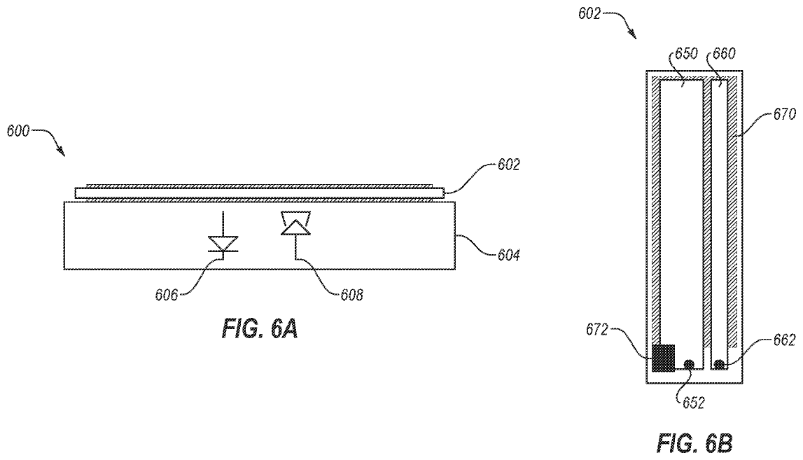

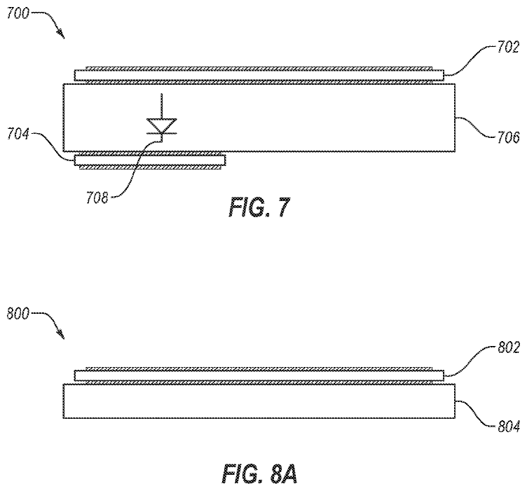

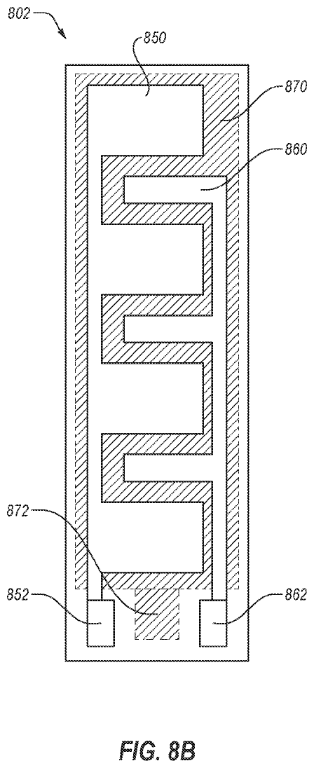

In these or other embodiments, the disclosed self-diagnosis apparatuses, including the self-diagnosis apparatus 600 of FIG. 6A, the self-diagnosis apparatus 700 of FIG. 7, and/or the self-diagnosis apparatus 800 of FIG. 8A, may be capable of determining an operational status of the piezo film sensor without measuring the environmental temperature, determining an operational status of the piezo film sensor independent of changes to the environmental temperature, determining one or more changes to the sensitivity of the piezo film sensor (e.g., a reduced sensitivity and/or a dead sensitivity), and/or determining if the piezo film sensor may be physically delaminated from a surface of the sensing object. Note that in instances in which the piezo film sensor is exposed to an excessive high temperature, such as greater than 85° C., the sensitivity of the piezo film sensor may be permanently reduced. Alternatively, or additionally, in instances in which the piezo film sensor is exposed to temperatures equal to or greater than 135° C. for two or more hours, the sensitivity of the piezo film sensor may be permanently damaged. In some embodiments, determining the delamination of the piezo film sensor relative to the surface of the sensing object may be accomplished when the piezo film sensor may be healthy and functional.

FIG. 6A illustrates an example embodiment of a self-diagnosis apparatus 600 including a piezo film, in accordance with at least one embodiment of the present disclosure. In some embodiments, the self-diagnosis apparatus 600 may include a piezo film 602, a sensing object 604, a drive signal 606, and reflected signal 608.

In some embodiments, the self-diagnosis apparatus 600 may be configured to determine an operational status associated with the piezo film 602 (which may include a primary piezo film sensor and/or a reference piezo film sensor, as described herein). In some embodiments, the operational status of the piezo film 602 may be determined using one or more of a capacitance test and/or a sensitivity test, as described herein. The capacitance test may include comparing reference capacitance of the piezo film 602 to a measured capacitance of the piezo film 602. The sensitivity test may include comparing a measured output of a portion of the piezo film 602 (e.g., the reference piezo film sensor) to a determined threshold range.

In some embodiments, a size, a shape, and/or a layout of the self-diagnosis apparatus 600 may vary depending on the application thereof. For example, the self-diagnosis apparatus 600 may be a rectangular shape that may be approximately 25 mm long and 15 mm wide, and the self-diagnosis apparatus 600 may be used in various applications that may include a bendable or flexible object. In another example, the self-diagnosis apparatus 600 may be a circular shape that may have a diameter of approximately 50 mm and may be used in a sports scoring application. Alternatively, or additionally, the size and/or shape of the self-diagnosis apparatus 600 may further vary corresponding to dimensions of a sensing object, such as the sensing object 604.

In some embodiments, the self-diagnosis apparatus 600 may be implemented in instances in which the sensing object 604 may be a thicker object (e.g., such as a 3 mm think or more sensing object made of plastic). Alternatively, or additionally, the self-diagnosis apparatus 600 may be implemented in instances in which the sensing object 604 may be a thinner object (e.g., such as 2 mm thick sensing object made of plastic). For the self-diagnosis apparatus 600, the sensing object 604 may be physically unrestricted and/or free to move. In some embodiments, the sensing object 604 may be a substrate.

In some embodiments, the sensing object 604 may include a higher acoustic impedance than the acoustic impedance of air. In some embodiments, the sensing object 604 may include various materials, such as plastic, glass, and/or metal.

In some embodiments, the piezo film 602 may be coupled to the sensing object 604 on a surface thereof. In some embodiments, the piezo film 602 may include one or more piezo film sensors. For example, the piezo film 602 may include two separately active piezo film sensors that may be combined in the piezo film 602. For example, the piezo film 602 may include a primary piezo film sensor and a reference piezo film sensor. In some embodiments, the primary piezo film sensor and the reference piezo film sensor may be laminated and/or bonded on one or more surfaces of the sensing object 604.

In some embodiments, a size, a shape, an electrode pattern, and/or a thickness of the primary piezo film sensor and/or the reference piezo film sensor may vary depending on the applications and/or the sensing object 604. In some embodiments, testing the sensitivity of the self-diagnosis apparatus 600 may include the piezo film 602 coupled on one side of the sensing object 604. For example, the primary piezo film sensor (e.g., a transmitter) and the reference piezo film sensor (e.g., a receiver) may be coupled on the same surface of the sensing object 604. An example piezo film including a primary piezo film sensor and a reference piezo film sensor is illustrated and described relative to FIG. 6B herein.

As shown in FIG. 6B, the piezo film 602 may include a primary piezo film sensor 650, a primary signal terminal 652, a reference piezo film sensor 660, a reference signal terminal 662, a negative electrode 670, and a ground terminal 672.

In some embodiments, a first positive electrode associated with the primary piezo film sensor 650, a second positive electrode associated with the reference piezo film sensor 660, and/or the negative electrode 670 may be disposed on a single piezo film (e.g., the piezo film 602 of FIG. 6A). A size and/or a shape associated with any of the first positive electrode, the second positive electrode, and/or the negative electrode 670 may vary depending on a size of the sensing object (e.g., the sensing object 604 of FIG. 6A) and/or a shape of the sensing object. In some embodiments, the primary piezo film sensor 650 may be used as a strain sensor for a particular application and the reference piezo film sensor 660 may be used for self-diagnosis methods of the self-diagnosis apparatus 600 as described herein, or vice versa.

In some embodiments, the primary signal terminal 652 may be coupled to the primary piezo film sensor 650 and may be configured to transmit and/or receive signals relative to the primary piezo film sensor 650. For example, in instances in which the primary piezo film sensor 650 transmits a drive signal as described herein, the drive signal may be transmitted via the primary signal terminal 652. In some embodiments, the reference signal terminal 662 may be coupled to the reference piezo film sensor 660 and may be configured to transmit and/or receive signals relative to the reference piezo film sensor 660. For example, in instances in which the reference piezo film sensor 660 generates an output in response to a drive signal as described herein, the output may be transmitted via the reference signal terminal 662. In some embodiments, the ground terminal 672 may be coupled to the negative electrode 670 and may be configured to transmit and/or receive signals relative to the negative electrode 670. For example, the negative electrode 670 and/or the ground terminal 672 may contribute to the piezo film 602 having characteristics similar to a capacitor, such as storing electric charge.

In some embodiments, combinations of the primary piezo film sensor 650 and the reference piezo film sensor 660 may be used to monitor the operational status of the piezo film 602 (e.g., the primary piezo film sensor 650 and/or the reference piezo film sensor 660). In instances in which one or both of the primary piezo film sensor 650 and the reference piezo film sensor 660 include an operational status that may be “not healthy”, the piezo film 602 and/or the self-diagnosis apparatus 600 may be considered not healthy and/or not functional.

In some embodiments, a reference capacitance may be obtained relative to the primary piezo film sensor 650 and/or the reference piezo film sensor 660 (e.g., a first reference capacitance and a second reference capacitance, respectively). In some embodiments, monitoring the operational status of the primary piezo film sensor 650 and/or the reference piezo film sensor 660 may include obtaining a first measured capacitance (e.g., associated with the primary piezo film sensor 650, Cₚ) and a second measured capacitance (e.g., associated with the reference piezo film sensor 660, Cᵣ), determining a capacitance ratio (Cₚ/Cᵣ) of the primary piezo film sensor 650 and the reference piezo film sensor 660, and comparing the capacitance ratio to a reference capacitance ratio (e.g., a ratio of the first reference capacitance relative to the second reference capacitance).

In some embodiments, the capacitance ratio may be a pre-determinable value relative to the primary piezo film sensor 650 and the reference piezo film sensor 660 based on characteristics of the primary piezo film sensor 650 and/or the reference piezo film sensor 660. For example, in instances in which the first reference capacitance of the primary piezo film sensor 650 is 2 nF and the second reference capacitance of the reference piezo film sensor 660 is 1 nF, then the reference capacitance ratio may be 2. In another example, the area of electrodes included in the primary piezo film sensor 650 and/or the reference piezo film sensor 660 may contribute to determining the capacitance ratio. In some embodiments, the area of the electrodes may vary according to an application in which the primary piezo film sensor 650 and the reference piezo film sensor 660 may be used.

In instances in which either of the primary piezo film sensor 650 and/or the reference piezo film sensor 660 may be physically damaged, then the first measured capacitance may change a first amount and the second measured capacitance may change a second amount, which may or may not be equal in amount. In some embodiments, the primary piezo film sensor 650 and/or the reference piezo film sensor 660 may be determined to be damaged in instances in which the first measured capacitance differs more than a threshold amount from the second measured capacitance. For example, in instances in which the first measured capacitance differs less than the threshold amount relative to the second measured capacitance, the primary piezo film sensor 650 and/or the reference piezo film sensor 660 may be determined to be healthy and/or functional. Therefore, the measured capacitance ratio between the primary piezo film sensor 650 and the reference piezo film sensor 660 may vary from the reference capacitance ratio. For example, a short circuit may result in infinite capacitance and an open circuit may cause zero capacitance. In instances in which the environmental temperature changes, the first measured capacitance of the primary piezo film sensor 650 and the second measured capacitance of the reference piezo film sensor 660 may change equally and thus, the capacitance ratio of the primary piezo film sensor 650 and the reference piezo film sensor 660 may remain the same. Therefore, in such instances, the change to the environmental temperature can be ignored.

In order to test the operational status of the sensitivity of the primary piezo film sensor 650 and/or the reference piezo film sensor 660, the primary piezo film sensor 650 may be used as a transmitter (or an emitter) and the reference piezo film sensor 660 may be used as a receiver, or vice versa.

Referring now to both FIGS. 6A and 6B, in some embodiments, the drive signal 606 may be an acoustic signal, such as an ultrasound acoustic signal. In instances in which the drive signal 606 is applied to the primary piezo film sensor 650, the drive signal 606 may be emitted from the primary piezo film sensor 650. The drive signal 606 may travel from a first side of the sensing object 604 through the sensing object 604 and may reflect back as the reflected signal 608 at the boundary of the second side of the sensing object 604. The reflected signal 608 may create a strain on the reference piezo film sensor 660 and thus, an acoustic signal may be generated on the reference piezo film sensor 660. Note that as the acoustic impedance of the material of the sensing object 604 (e.g., Z1) may be much higher than the acoustic impedance of air (e.g., Z2), most or all of the drive signal 606 may be reflected at the boundary of the sensing object 604, as represented by the equation:

$$R = \frac{{( {Z}_{1} - {Z}_{2} )}^{2}}{{( {Z}_{1} + {Z}_{2} )}^{2}} ≅ 1$$

where R may be a reflection coefficient, Z₁ may be the acoustic impedance of the sensing object 604, and Z₂ may be the acoustic impedance of air. In an example, the acoustic impedance of the sensing object 604 (e.g., Z₁) may be approximately 4.6*10⁶ Rayl and the acoustic impedance of air (e.g., Z₂) may be approximately 385 Rayl, such that the reflection coefficient may be approximately equal to one and substantially all of an emitted wave may be reflected at a boundary between the sensing object 604 and air.

In some embodiments, an amplitude of the reflected signal 608 of the reference piezo film sensor 660 may be proportional to the sensitivity of the primary piezo film sensor 650 and/or the reference piezo film sensor 660. Therefore, by monitoring the amplitude of the reflected signal 608 at the reference piezo film sensor 660 in view of the drive signal 606 (e.g., the frequency and amplitude of the drive signal 606), the sensitivity of the primary piezo film sensor 650 and/or the reference piezo film sensor 660 may be determined.

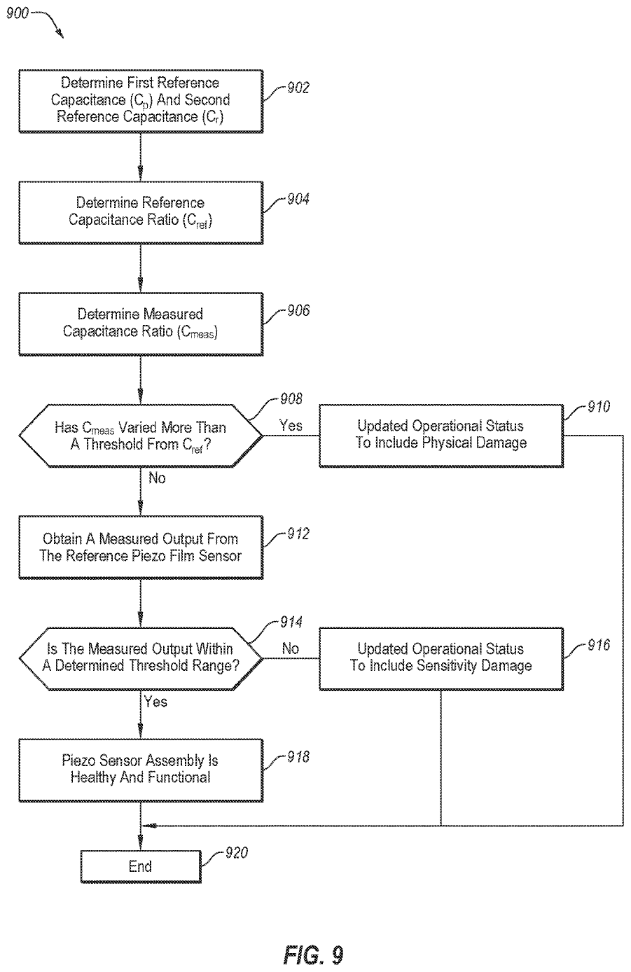

In these or other embodiments, determining the sensitivity of the primary piezo film sensor 650 and/or the sensitivity of the reference piezo film sensor 660 may be used to determine at least a portion of the operational status of the piezo film 602 (e.g., the primary piezo film sensor 650 and/or the reference piezo film sensor 660). For example, in instances in which the reference piezo film sensor 660 produces an output in response to a drive signal from the primary piezo film sensor 650 that is greater than or less than a threshold, the primary piezo film sensor 650 and/or the reference piezo film sensor 660 may have sensitivity damage, such as a loss or degradation to a sensing function of the primary piezo film sensor 650 and/or the reference piezo film sensor 660 and/or a physical separation of the primary piezo film sensor 650 and/or the reference piezo film sensor 660 from the sensing object. Additional details related to the sensitivity and/or the operational status associated with the piezo film 602 may be discussed relative to FIG. 9 herein.

FIG. 7 illustrates an example embodiment of a self-diagnosis apparatus 700 including two piezo film sensors, in accordance with at least one embodiment of the present disclosure. In some embodiments, the self-diagnosis apparatus 700 may include a primary piezo film sensor 702, a reference piezo film sensor 704, a sensing object 706, and a drive signal 708.

In some embodiments, the self-diagnosis apparatus 700 may be configured to determine an operational status associated with the primary piezo film sensor 702 and/or the reference piezo film sensor 704. In some embodiments, the operational status may be determined using one or more of a capacitance test and/or a sensitivity test, as described herein. The capacitance test may include comparing reference capacitance of the primary piezo film sensor 702 and the reference piezo film sensor 704 to a measured capacitance of the primary piezo film sensor 702 and the reference piezo film sensor 704. The sensitivity test may include comparing a measured output of the reference piezo film sensor 704 to a determined threshold range.

In some embodiments, the self-diagnosis apparatus 700 may include the primary piezo film sensor 702 (e.g., a transmitter, which may be similar to the primary piezo film sensor 650 described relative to FIG. 6B) and the reference piezo film sensor (e.g., a receiver, which may be similar to the reference piezo film sensor 660 described relative to FIG. 6B) coupled on opposite surfaces of the sensing object 706.

In some embodiments, a size, a shape, and/or a layout of the self-diagnosis apparatus 700 may vary depending on the application thereof. For example, the self-diagnosis apparatus 700 may be a rectangular shape that may be approximately 25 mm long and 15 mm wide, and the self-diagnosis apparatus 700 may be used in various applications that may include a bendable or flexible object. In another example, the self-diagnosis apparatus 700 may be a circular shape that may have a diameter of approximately 50 mm and may be used in a sports scoring application. Alternatively, or additionally, the size and/or shape of the self-diagnosis apparatus 700 may further vary corresponding to dimensions of a sensing object, such as the sensing object 706.

In some embodiments, the self-diagnosis apparatus 700 may be implemented in instances in which the sensing object 706 may be a thicker object (e.g., such as a 3 mm think or more sensing object made of plastic). Alternatively, or additionally, the self-diagnosis apparatus 700 may be implemented in instances in which the sensing object 706 may be a thinner object (e.g., such as 2 mm thick sensing object made of plastic). For the self-diagnosis apparatus 700, the sensing object 706 may be physically unrestricted and/or free to move. In some embodiments, the sensing object 706 may be a substrate.

In some embodiments, a reference capacitance may be obtained relative to the primary piezo film sensor 702 and/or the reference piezo film sensor 704 (e.g., a first reference capacitance and a second reference capacitance, respectively). In some embodiments, monitoring the operational status of the primary piezo film sensor 702 and/or the reference piezo film sensor 704 may include obtaining a first measured capacitance (e.g., associated with the primary piezo film sensor 702, Cₚ) and a second measured capacitance (e.g., associated with the reference piezo film sensor 704, Cᵣ), determining a capacitance ratio (Cₚ/Cᵣ) of the primary piezo film sensor 702 and the reference piezo film sensor 704, and comparing the capacitance ratio to a reference capacitance ratio (e.g., a ratio of the first reference capacitance relative to the second reference capacitance).

In some embodiments, the capacitance ratio may be a pre-determinable value relative to the primary piezo film sensor 702 and the reference piezo film sensor 704 based on characteristics of the primary piezo film sensor 702 and/or the reference piezo film sensor 704. For example, in instances in which the first reference capacitance of the primary piezo film sensor 702 is 2 nF and the second reference capacitance of the reference piezo film sensor 704 is 1 nF, then the reference capacitance ratio may be 2.

In instances in which either of the primary piezo film sensor 702 and/or the reference piezo film sensor 704 may be physically damaged, then the first measured capacitance may change a first amount and the second measured capacitance may change a second amount, which may or may not be equal in amount. In some embodiments, the primary piezo film sensor 702 and/or the reference piezo film sensor 704 may be determined to be damaged in instances in which the first measured capacitance differs more than a threshold amount from the second measured capacitance. For example, in instances in which the first measured capacitance differs less than the threshold amount relative to the second measured capacitance, the primary piezo film sensor 702 and/or the reference piezo film sensor 704 may be determined to be healthy and/or functional. Therefore, the capacitance ratio between the primary piezo film sensor 702 and the reference piezo film sensor 704 may vary from the reference capacitance ratio. For example, a short circuit may result in infinite capacitance and an open circuit may cause zero capacitance. In instances in which the environmental temperature changes, the first measured capacitance of the primary piezo film sensor 702 and the second measured capacitance of the reference piezo film sensor 704 may change equally and thus, the capacitance ratio of the primary piezo film sensor 702 and the reference piezo film sensor 704 may remain the same. Therefore, in such instances, the change to the environmental temperature may be ignored.

In order to test the operational status of the sensitivity of the primary piezo film sensor 702 and/or the reference piezo film sensor 704, the primary piezo film sensor 702 may be used as a transmitter (or an emitter) and the reference piezo film sensor 704 may be used as a receiver, or vice versa.

In some embodiments, the drive signal 708 may be an acoustic signal, such as an acoustic ultrasound signal. In instances in which the drive signal 708 is applied to the primary piezo film sensor 702, the drive signal 708 may be emitted from the primary piezo film sensor 702. The drive signal 708 may travel as an acoustic wave through the sensing object 706 and the drive signal 708 may create a strain on the reference piezo film sensor 704 on the opposite side of the sensing object 706. Alternatively, or additionally, the drive signal 708 may be generated on the reference piezo film sensor 704 and may be transmitted to the primary piezo film sensor 702 through the sensing object 706.

In some embodiments, a signal amplitude of a signal generated by the reference piezo film sensor 704 in response to the drive signal 708 may be proportional to a sensitivity of the primary piezo film sensor 702 and/or a sensitivity of the reference piezo film sensor 704. Therefore, by monitoring the signal amplitude generated by the reference piezo film sensor 704, the sensitivity of the primary piezo film sensor 702 and/or the reference piezo film sensor 704 may be determined.

In some embodiments, the drive signal 708 may experience a time delay between a transmission time relative to the primary piezo film sensor 702 and a reception time relative to the reference piezo film sensor 704. In some embodiments, the time delay may be proportional to a thickness of the sensing object 706. For example, a first sensing object having a first thickness may cause a first propagation time and a second sensing object having a second thickness that is greater than the first thickness, may cause a second propagation time that is greater than the first propagation time.

FIG. 8A illustrates an example embodiment of a self-diagnosis apparatus 800 including a piezo film, in accordance with at least one embodiment of the present disclosure. In some embodiments, the self-diagnosis apparatus 800 may include a piezo film 802 and a sensing object 804, in accordance with at least one embodiment of the present disclosure.

In some embodiments, the self-diagnosis apparatus 800 may be configured to determine an operational status associated with the piezo film 802 (which may include a primary piezo film sensor and/or a reference piezo film sensor, as described herein). In some embodiments, the operational status of the piezo film 802 may be determined using one or more of a capacitance test and/or a sensitivity test, as described herein. The capacitance test may include comparing reference capacitance of the piezo film 802 to a measured capacitance of the piezo film 802. The sensitivity test may include comparing a measured output of a portion of the piezo film 802 (e.g., the reference piezo film sensor) to a determined threshold range.

In some embodiments, the piezo film 802 may be coupled to the sensing object 804 on a surface thereof. In some embodiments, the piezo film 802 may include one or more piezo film sensors. For example, the piezo film 802 may include two separately active piezo film sensors that may be combined in the piezo film 802. For example, the piezo film 802 may include a primary piezo film sensor and a reference piezo film sensor. In some embodiments, the primary piezo film sensor and the reference piezo film sensor may be laminated and/or bonded on one or more surfaces of the sensing object 804.

In some embodiments, a size, a shape, an electrode pattern, and/or a thickness of the primary piezo film sensor and/or the reference piezo film sensor may vary depending on the applications and/or the sensing object 804. In some embodiments, an electrode size and/or an electrode shape associated with the primary piezo film sensor and/or the reference piezo film sensor may vary depending on a size of the sensing object 804 and/or a shape of the sensing object 804.

In some embodiments, testing the sensitivity of the self-diagnosis apparatus 800 may include the piezo film 802 coupled on one side of the sensing object 804. For example, the primary piezo film sensor and the reference piezo film sensor may be coupled on the same surface of the sensing object 804. An example piezo film including a primary piezo film sensor and a reference piezo film sensor is illustrated and described relative to FIG. 8B herein.

As shown in FIG. 8B, the piezo film 802 may include a primary piezo film sensor 850, a primary signal terminal 852, a reference piezo film sensor 860, a reference signal terminal 862, a negative electrode 870, and a ground terminal 872.

In some embodiments, the primary piezo film sensor 850 and the reference piezo film sensor 860 may include an interdigitated electrode pattern. For example, one or more portions of the primary piezo film sensor 850 may extend into one or more corresponding portions of the reference piezo film sensor 860, and vice versa. In some embodiments, the primary piezo film sensor 850 and the reference piezo film sensor 860 may be disposed on the piezo film 802.

In some embodiments, the primary signal terminal 852 may be coupled to the primary piezo film sensor 850 and may be configured to transmit and/or receive signals relative to the primary piezo film sensor 850. For example, in instances in which the primary piezo film sensor 850 transmits a drive signal as described herein, the drive signal may be transmitted via the primary signal terminal 852. In some embodiments, the reference signal terminal 862 may be coupled to the reference piezo film sensor 860 and may be configured to transmit and/or receive signals relative to the reference piezo film sensor 860. For example, in instances in which the reference piezo film sensor 860 generates an output in response to a drive signal as described herein, the output may be transmitted via the reference signal terminal 862. In some embodiments, the ground terminal 872 may be coupled to the negative electrode 870 and may be configured to transmit and/or receive signals relative to the negative electrode 870. For example, the negative electrode 870 and/or the ground terminal 872 may contribute to the piezo film 802 having characteristics similar to a capacitor, such as storing electric charge.

In some embodiments, a reference capacitance may be obtained relative to the primary piezo film sensor 850 and/or the reference piezo film sensor 860 (e.g., a first reference capacitance and a second reference capacitance, respectively). In some embodiments, monitoring the operational status of the primary piezo film sensor 850 and/or the reference piezo film sensor 860 may include obtaining a first measured capacitance (e.g., associated with the primary piezo film sensor 850, Cₚ) and a second measured capacitance (e.g., associated with the reference piezo film sensor 860, Cᵣ), determining a capacitance ratio (Cₚ/Cᵣ) of the primary piezo film sensor 850 and the reference piezo film sensor 860, and comparing the capacitance ratio to a reference capacitance ratio (e.g., a ratio of the first reference capacitance relative to the second reference capacitance).

In some embodiments, the capacitance ratio may be a pre-determinable value relative to the primary piezo film sensor 850 and the reference piezo film sensor 860 based on characteristics of the primary piezo film sensor 850 and/or the reference piezo film sensor 860. For example, in instances in which the first reference capacitance of the primary piezo film sensor 850 is 2 nF and the second reference capacitance of the reference piezo film sensor 860 is 1 nF, then the reference capacitance ratio may be 2.

In instances in which either of the primary piezo film sensor 850 and/or the reference piezo film sensor 860 may be physically damaged, then the first measured capacitance may change a first amount and the second measured capacitance may change a second amount, which may or may not be equal in amount. In some embodiments, the primary piezo film sensor 850 and/or the reference piezo film sensor 860 may be determined to be damaged in instances in which the first measured capacitance differs more than a threshold amount from the second measured capacitance. For example, in instances in which the first measured capacitance differs less than the threshold amount relative to the second measured capacitance, the primary piezo film sensor 850 and/or the reference piezo film sensor 860 may be determined to be healthy and/or functional. Therefore, the capacitance ratio between the primary piezo film sensor 850 and the reference piezo film sensor 860 may vary from the reference capacitance ratio. For example, a short circuit may result in infinite capacitance and an open circuit may cause zero capacitance. In instances in which the environmental temperature changes, the first measured capacitance of the primary piezo film sensor 850 and the second measured capacitance of the reference piezo film sensor 860 may change equally and thus, the capacitance ratio of the primary piezo film sensor 850 and the reference piezo film sensor 860 may remain the same. Therefore, in such instances, the change to the environmental temperature can be ignored.

In order to test the operational status of the sensitivity of the primary piezo film sensor 850 and/or the reference piezo film sensor 860, the primary piezo film sensor 850 may be used as a transmitter (or an emitter) and the reference piezo film sensor 860 may be used as a receiver, or vice versa.

In some embodiments, a drive signal may be applied to the primary piezo film sensor 850 which may create a bending motion on a sensing object in which the piezo film 802 may be coupled (such as the sensing object 804 of FIG. 8A). In some embodiments, the drive signal may be a low frequency signal. In instances in which a positive drive voltage is applied to the primary piezo film sensor 850, the primary piezo film sensor 850 may stretch and/or may cause the sensing object to bend in a first direction. In some embodiments, the bending of the sensing object may cause the reference piezo film sensor 860 to bend in the first direction and thus the reference piezo film sensor 860 may generate an output signal. In some embodiments, the frequency and/or voltage of the drive signal may vary depending on the size, the shape, and/or the material of the sensing object.

In some embodiments, the sensing object may be physically unrestricted relative to any other objects and/or the sensing object may be free to move. For example, the sensing object may be physically disconnected from any objects that may cause a damping effect in the piezo film 802 and/or that may restrict the sensing object from bending, which may also reduce the effectiveness of the piezo film 802.

In some embodiments, a frequency and/or a voltage of the drive signal may vary depending on the size, the shape, and/or the material of the sensing object. For example, the frequency range of the drive signal may vary between 10 Hz and 1 KHz and/or the voltage of the drive signal may range between 10 V and 100 V. Alternatively, or additionally, the frequency and/or the voltage of the drive signal may vary based on characteristics of the piezo film 802, such as a thickness of the piezo film 802 and/or a length of the piezo film 802. In some embodiments, the drive signal may be discontinuous, such as a pulse signal, or a short burst signal.

In some embodiments, an amplitude of an output of the reference piezo film sensor 860 may be proportional to a sensitivity of the primary piezo film sensor 850 and/or the reference piezo film sensor 860. Therefore, by monitoring the amplitude of the output of the reference piezo film sensor 860, the sensitivity of the primary piezo film sensor 850 and/or the sensitivity of the reference piezo film sensor 860 may be determined.

In these or other embodiments, determining the sensitivity of the primary piezo film sensor 850 and/or the sensitivity of the reference piezo film sensor 860 may be used to determine at least a portion of the operational status of the piezo film 802 (e.g., the primary piezo film sensor 850 and/or the reference piezo film sensor 860). For example, in instances in which the reference piezo film sensor 860 produces an output in response to a drive signal from the primary piezo film sensor 850 that is greater than or less than a threshold, the primary piezo film sensor 850 and/or the reference piezo film sensor 860 may have sensitivity damage, such as a loss or degradation to a sensing function of the primary piezo film sensor 850 and/or the reference piezo film sensor 860 and/or a physical separation of the primary piezo film sensor 850 and/or the reference piezo film sensor 860 from the sensing object. Additional details related to the sensitivity and/or the operational status associated with the piezo film 802 may be discussed relative to FIG. 9 herein.

FIG. 9 illustrates a flowchart of a self-diagnosis process 900 for a piezo film sensor, in accordance with at least one embodiment of the present disclosure. In some embodiments, the self-diagnosis process 900 may begin at block 902, where a first reference capacitance (Cₚ) may be determined for a primary piezo film sensor and/or a second reference capacitance (Cᵣ) may be determined for a reference piezo film sensor, such as described herein. In these or other embodiments, the first reference capacitance and/or the second reference capacitance may be based on one or more characteristics associated with the primary piezo film sensor and/or the reference piezo film sensor. For example, the first reference capacitance and/or the second reference capacitance may be associated with an amount of electrical capacitance that the primary piezo film sensor and/or the reference piezo film sensor may hold in a given condition and/or a known environment. In these or other embodiments, the first reference capacitance and/or the second reference capacitance may be a predetermined value that may be based on a configuration of the primary piezo film sensor and/or the reference piezo film sensor.

At block 904, a reference capacitance ratio (C_{ref}) may be determined. The reference capacitance ratio may be a ratio of the first reference capacitance relative to the second reference capacitance, or the ratio Cₚ/Cᵣ. In some embodiments, the reference capacitance ratio may be a unitless value and/or may represent the amount of capacitance stored in the primary piezo film sensor relative to the reference piezo film sensor. In some embodiments, the reference capacitance ration may vary based on a configuration of the primary piezo film sensor and the reference piezo film sensor. For example, the self-diagnosis apparatus 600 of FIG. 6A, the self-diagnosis apparatus 700 of FIG. 7, and/or the self-diagnosis apparatus 800 of FIG. 8A may individually include a different reference capacitance ratio.

At block 906, a measured capacitance ratio (Cₘₑₐₛ) may be determined. The measured capacitance ratio may be a ratio of a measured capacitance associated with the primary piezo film sensor relative to a measured capacitance associated with the reference piezo film sensor. In some embodiments, the measured capacitance ratio may be a unitless value and/or may represent the amount of capacitance stored in the primary piezo film sensor relative to the reference piezo film sensor. In some embodiments, the measured capacitance ratio may be determined at a point in time after the primary piezo film sensor and/or the reference piezo film sensor may have been attached to a sensing object.

At block 908, the measured capacitance ratio may be compared to the reference capacitance ratio to determine an amount of change that may have occurred between the measured capacitance ratio and the reference capacitance ratio. In some embodiments, a difference based on the comparison may be compared to a threshold value. In instances in which the measured capacitance ratio changes relative to the reference capacitance ratio more than or less than the threshold value, a first determination may be made regarding an operational status of the primary piezo film sensor and/or the reference piezo film sensor, as described relative to block 910. For example, in instances in which the threshold value is +/−20% and the measured capacitance ratio is more than or less than the reference capacitance ratio times the threshold value (e.g., C_{ref}*0.20), the first determination regarding the operational status may be made, as described at block 910.

Alternatively, or additionally, in instances in which the measured capacitance ratio changes relative to the reference capacitance ratio less than or equal to the threshold value, a second determination may be made regarding an operational status of the primary piezo film sensor and/or the reference piezo film sensor. The second determination may be that the measured capacitance of the primary piezo film sensor and/or the reference piezo film sensor is within an acceptable range, which acceptable range may be defined in a lookup table, such as illustrated in Table 1 herein. In these and other embodiments, the method may proceed to block 912.

At block 910, the operational status associated with the primary piezo film sensor and/or the reference piezo film sensor may be updated to indicate a potential issue with the primary piezo film sensor and/or the reference piezo film sensor. For example, based on the results from block 908 (e.g., the difference between the measured capacitance ratio and the reference capacitance ratio relative to the threshold), the operational status associated with the primary piezo film sensor and/or the reference piezo film sensor may be updated to include a physical damage to the primary piezo film sensor and/or the reference piezo film sensor. In some embodiments, the physical damage may include, but not be limited to, a short circuit, one or more broken wires, one or more damaged electrodes, etc.

At block 912, a measured output from the reference piezo film sensor may be obtained. The measured output may be in response to a drive signal, where the drive signal may include a voltage and/or a frequency. In some embodiments, the drive signal may be transmitted from the primary piezo film sensor to the reference piezo film sensor, as described herein.

At block 914, the measured output from the reference piezo film sensor may be compared to a determined threshold range. In some embodiments, the determined threshold range may be included in a lookup table, such as illustrated in Table 1 herein. In instances in which the measured output is greater than or less than the determined threshold range, the operational status of the primary piezo film sensor and/or the reference piezo film sensor may be updated, as described at block 916. Alternatively, in instances in which the measured output is within the determined threshold range, at block 918, the primary piezo film sensor and/or the reference piezo film sensor may be determined to be healthy and/or functional. In some embodiments, the lookup table may include a temperature compensation element, such that the temperature in which the reference piezo film sensor may be accounted for in determining whether the measured output is within the determined threshold range.

At block 916, the operational status associated with the primary piezo film sensor and/or the reference piezo film sensor may be updated to indicate a potential issue with the primary piezo film sensor and/or the reference piezo film sensor. For example, based on the results from block 914 (e.g., the comparison of the measured output relative to the determined threshold range), the operational status associated with the primary piezo film sensor and/or the reference piezo film sensor may be updated to include a sensitivity damage to the primary piezo film sensor and/or the reference piezo film sensor. In some embodiments, the sensitivity damage may include, but not be limited to, degraded or dead sensitivity to stress or strain, physical delamination from the sensing object, etc.

At block 920, the self-diagnosis process 900 may end, where the reference piezo film sensor (or in some arrangements, the primary piezo film sensor) may be disabled and/or powered off, and the primary piezo film sensor may perform the sensing function relative to the sensing object to which the primary piezo film sensor is coupled.

An example lookup table that may be used as part of block 908 and/or block 914 is shown herein in Table 1.

TABLE 1
Example lookup table for self-diagnosis of sensitivity of a piezo film sensor

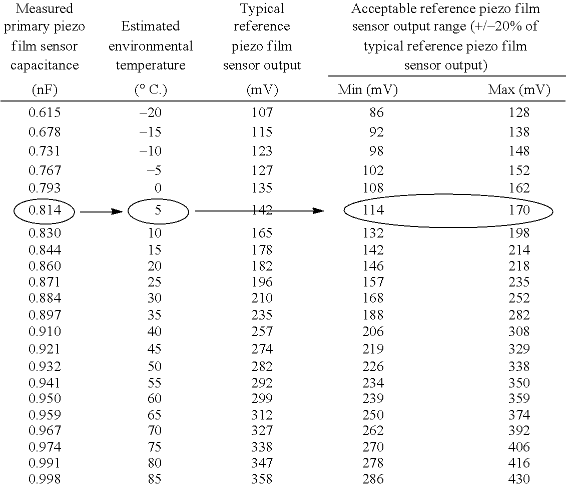

In an example using a portion the self-diagnosis process 900 and the lookup table of Table 1, in instances in which the measured capacitance of a primary piezo film sensor is 0.81 nF, the measured output of a reference piezo film sensor is 130 mV, and the estimated environmental temperature is approximately 5° C., then the determined threshold range for the reference piezo film sensor may be approximately 114 mV to 170 mV. As shown, the output of the reference piezo film sensor (e.g., 130 mV) is within the acceptable output range. Therefore, the sensitivity (e.g., the operational status) of the tested self-diagnosis embodiment is healthy and/or functional.

In some embodiments, the lookup table may be customized depending on a configuration of a self-diagnosis apparatus, such as the self-diagnosis apparatus 600 of FIG. 6A, the self-diagnosis apparatus 700 of FIG. 7, and/or the self-diagnosis apparatus 800 of FIG. 8A. In some embodiments, the lookup table may include various columns that may be used in various determinations as part of the self-diagnosis process 900. For example, the lookup table may include columns such as “Primary piezo film sensor capacitance vs. Environmental temperature”, “Environmental temperature vs. Typical reference piezo film sensor output” and/or “Acceptable reference piezo film sensor output ranges”, as shown in Table 1.

The typical reference piezo film sensor outputs may be the measured reference piezo film sensor outputs based on a drive signal that may be predetermined (e.g., a drive signal having a known signal amplitude, frequency, and/or waveform) which may be applied to the primary piezo film sensor. For example, the typical reference piezo film sensor outputs may align with the measured output from the reference piezo film sensor for given temperatures in circumstances in which the reference piezo film sensor is healthy and/or functional.

In some embodiments, the acceptable reference piezo film sensor output range may be the determined threshold range, which may be a tolerance of the measured output of the reference piezo film sensor (e.g., +/−20% of the typical reference piezo film sensor output, as an example) caused by the sensitivity variance between a first piezo film sensor to a second piezo film sensor. The determined threshold range may vary depending on the application and/or the configuration of the primary piezo film sensor and/or the reference piezo film sensor, such as the self-diagnosis apparatus 600 of FIG. 6A, the self-diagnosis apparatus 700 of FIG. 7, and/or the self-diagnosis apparatus 800 of FIG. 8A.

In instances in which the measured capacitance of the primary piezo film sensor is 81 nF, the estimated environmental temperature may be approximately 5° C., based on Table 1. Therefore, an acceptable reference piezo film sensor output range may be approximately 114 mV to 170 mV, which may be approximately +/−20% (e.g., the determined threshold range) of the typical reference piezo film sensor output. If the measured output of the reference piezo film sensor was 130 mV, then the measured output is within the acceptable reference piezo film sensor output range of 114 mV-170 mV at 5° C. Therefore, the operational status (e.g., the sensitivity) of the tested self-diagnosis apparatus may be considered healthy and/or functional.

In some embodiments, the self-diagnosis process 900 may be described in one or more steps. In a first step, a measurement of the primary piezo film sensor capacitance (Cₚ) and the reference piezo film sensor capacitance (Cᵣ) may be obtained. The capacitance ratio (Cₘₑₐₛ defined as Cₚ/Cᵣ) may be compared with a reference capacitance ratio, which may be determined prior to obtaining the primary piezo film sensor capacitance and/or the reference piezo film sensor capacitance. In instances in which the capacitance ratio (Cₚ/Cᵣ) is changed by more than a threshold value (e.g., +/−20%) of the reference capacitance ratio, the primary piezo film sensor and/or the reference piezo film sensor may be considered to be physically damaged. The +/−20% threshold value may be an example of a sensor-to-sensor capacitance tolerance caused by a thickness and/or a dielectric constant variance relative to the primary piezo film sensor and/or the reference piezo film sensor. The tolerance may vary based on the piezo film sensor configuration and/or the piezo film sensor application. In some embodiments, the damaged sensor scenario may include a broken wire (e.g., an open circuit), a short circuit, a partially damaged and/or delaminated electrodes, and/or a partially damaged or cut piezo film sensor. In instances in which the capacitance ratio is within the threshold value of the reference capacitance ratio, then the operational status of both the primary piezo film sensor and the reference piezo film sensor may be considered as healthy and/or functional.

In a second step a drive signal (e.g., including a signal amplitude, a frequency, and/or a waveform) may be applied to the primary piezo film sensor and a measured output from the reference piezo film sensor may be obtained. The capacitance of the primary piezo film sensor may be used to estimate the environmental temperature and subsequently, an “Acceptable reference piezo film sensor output range” may be determined from a lookup table, such as shown in Table 1. In instances in which the measured output from the reference piezo film sensor is within a determined threshold range, such as the “Acceptable reference piezo film sensor output range” from the lookup table, the self-diagnosis apparatus may be considered healthy. Otherwise, the sensitivity of the primary piezo film sensor and/or the sensitivity of the reference piezo film sensor may be dead and/or not functional. Alternatively, or additionally, the primary piezo film sensor and/or the reference piezo film sensor may be delaminated from a surface of the sensing object. The determined threshold range (e.g., +/−20%) may be an example of the sensor-to-sensor sensitivity tolerance. The sensor-to-sensor sensitivity tolerance may vary based on the piezo film sensor configuration (e.g., the self-diagnosis apparatus 600 of FIG. 6A, the self-diagnosis apparatus 700 of FIG. 7, and/or the self-diagnosis apparatus 800 of FIG. 8A) and/or the piezo film sensor applications.

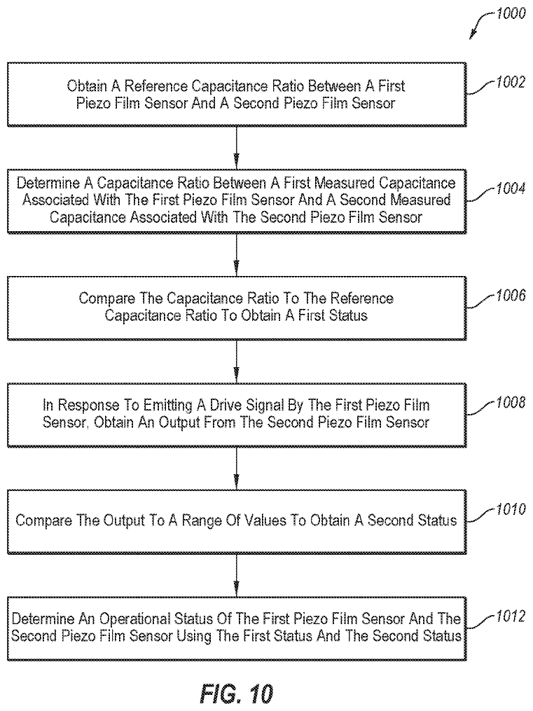

FIG. 10 is a flowchart of an example method 1000 of a self-diagnosis process for a piezo film sensor, in accordance with at least one embodiment of the present disclosure. One or more operations of the method 1000 may be performed, in some embodiments, by a device or system, or combination of devices or systems. Although illustrated as discrete blocks, various blocks may be divided into additional blocks, combined into fewer blocks, or eliminated, depending on the desired implementation.

The method 1000 may begin at block 1002 where a reference capacitance ratio between a first piezo film sensor and a second piezo film sensor may be obtained. In some embodiments, the first piezo film sensor may be mounted on a first side of a sensing object and the second piezo film sensor may be mounted on a second side of the sensing object opposite the first side. Alternatively, or additionally, the first piezo film sensor may be mounted on a first side of a sensing object and the second piezo film sensor may be mounted on the first side of the sensing object.

At block 1004, a capacitance ratio between a first measured capacitance associated with the first piezo film sensor and a second measured capacitance associated with the second piezo film sensor may be determined.

At block 1006, the capacitance ratio may be compared to the reference capacitance ratio to obtain a first status. In some embodiments, the first status may be associated with physical damage associated with the first piezo film sensor and/or the second piezo film sensor. For example, the first status may be associated with a short circuit, one or more broken wires, one or more damaged electrodes, etc., in the first piezo film sensor and/or the second piezo film sensor.

At block 1008, an output from the second piezo film sensor may be obtained in response an emitted drive signal from the first piezo film sensor. In some embodiments, the emitted drive signal may be transmitted from the first piezo film sensor through the sensing object to the second piezo film sensor. Alternatively, or additionally, the emitted drive signal may be transmitted from the first piezo film sensor into the sensing object and may reflect off a boundary thereof to the second piezo film sensor. In these or other embodiments, the emitted drive signal may include one of a high frequency ultrasound acoustic signal or a low frequency voltage signal.

At block 1010, the output may be compared to a range of values to obtain a second status. In some embodiments, the second status may be associated with a sensitivity associated with the first piezo film sensor and/or the second piezo film sensor. For example, the second status may be associated with a damaged or dead piezo film sensor, a physical delamination of the piezo film sensor from the sensing object, etc., in the first piezo film sensor and/or the second piezo film sensor.

In some embodiments, the range of values may be included in a data storage. For example, the range of values may be stored in a lookup table configuration. In some embodiments, the lookup table may include an estimated environmental temperature based on the first measured capacitance. Alternatively, or additionally, the range of values may correspond to an expected voltage with respect to the output. In some embodiments, the expected voltage may be based on at least the estimated environmental temperature.

At block 1012, an operational status of the first piezo film sensor and the second piezo film sensor may be determined using the first status and the second status. For example, the operational status may describe a physical damage and/or a change in sensitivity as described herein. Alternatively, or additionally, the operational status may indicate the first piezo film sensor and/or the second piezo film sensor may be healthy and/or functional.

Modifications, additions, or omissions may be made to the method 1000 without departing from the scope of the present disclosure. For example, in some embodiments, the method 1000 may include any number of other components that may not be explicitly illustrated or described.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc. Additionally, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B” even if the term “and/or” is used elsewhere.

All examples and conditional language recited in the present disclosure are intended for pedagogical objects to aid the reader in understanding the present disclosure and the concepts contributed by the inventor to furthering the art, and are to be construed as being without limitation to such specifically recited examples and conditions. Although embodiments of the present disclosure have been described in detail, various changes, substitutions, and alterations could be made hereto without departing from the spirit and scope of the present disclosure.

What is claimed is:

1. A system comprising:
a first piezo film sensor coupled to a sensing object, the first piezo film sensor having at least one first parameter and configured to emit a drive signal; and
a second piezo film sensor coupled to the sensing object, the second piezo film sensor having at least one second parameter, the second piezo film sensor configured to receive the drive signal and generate an output based on the drive signal;
wherein a first operational status associated with the first piezo film sensor and a second operational status associated with the second piezo film sensor is determined using the first parameter, the second parameter, and the output.

2. The system of claim 1, wherein the at least one first parameter comprises a first reference capacitance and a first measured capacitance, and the at least one second parameter comprises a second reference capacitance and a second measured capacitance.

3. The system of claim 1, wherein the first piezo film sensor is mounted on a first side of the sensing object and the second piezo film sensor is mounted on a second side of the sensing object opposite the first side.

4. The system of claim 1, wherein the first piezo film sensor is mounted on a first side of the sensing object and the second piezo film sensor is mounted on the first side.

5. The system of claim 4, wherein the first piezo film sensor and the second piezo film sensor include interdigitated positive electrodes and a common negative electrode.

6. The system of claim 1, wherein the drive signal is a high frequency ultrasound acoustic signal.

7. The system of claim 6, wherein a frequency of the high frequency ultrasound acoustic signal matches a resonance frequency of a piezo film sheet associated with the first piezo film sensor.

8. The system of claim 1, wherein the drive signal is a low frequency voltage signal that causes the first piezo film sensor to stretch, the second piezo film sensor to stretch, and the sensing object to bend.

9. The system of claim 2, further comprising a lookup table that is referenced to determine at least the first operational status and the second operational status.

10. The system of claim 9, wherein the lookup table includes an estimated environmental temperature based on the first measured capacitance.

11. The system of claim 10, wherein the lookup table includes a range of voltages corresponding to an expected voltage with respect to the output, the expected voltage based on at least the estimated environmental temperature.

12. The system of claim 11, wherein the range of voltages in the lookup table vary based on a configuration of the first piezo film sensor and the second piezo film sensor.

13. The system of claim 11, wherein the range of voltages in the lookup table vary based on an application in which the first piezo film sensor and the second piezo film sensor are used.

14. The system of claim 1, wherein the sensing object is comprised of plastic, glass, or a metallic plate.

15. The system of claim 1, wherein the drive signal causes a strain in the second piezo film sensor and the second piezo film sensor generates the output based on the strain.

16. A method comprising:
obtaining a reference capacitance ratio between a first piezo film sensor and a second piezo film sensor;
determining a capacitance ratio between a first measured capacitance associated with the first piezo film sensor and a second measured capacitance associated with the second piezo film sensor;
comparing the capacitance ratio to the reference capacitance ratio to obtain a first status;
in response to an emitted drive signal from the first piezo film sensor, obtaining an output from the second piezo film sensor;
comparing the output to a range of values to obtain a second status; and
determining an operational status of the first piezo film sensor and the second piezo film sensor using the first status and the second status.

17. The method of claim 16, wherein the range of values are included in a data storage, the data storage comprising an estimated environmental temperature based on the first measured capacitance and the range of values correspond to an expected voltage with respect to the output, the expected voltage based on at least the estimated environmental temperature.

18. The method of claim 16, wherein the first piezo film sensor is mounted on a first side of a sensing object and the second piezo film sensor is mounted on a second side of the sensing object opposite the first side, and the emitted drive signal is transmitted from the first piezo film sensor through the sensing object to the second piezo film sensor.

19. The method of claim 16, wherein the first piezo film sensor is mounted on a first side of a sensing object and the second piezo film sensor is mounted on the first side, and the emitted drive signal is transmitted from the first piezo film sensor into the sensing object and reflects off a boundary thereof to the second piezo film sensor.

20. The method of claim 16, wherein the emitted drive signal includes one of a high frequency ultrasound acoustic signal or a low frequency voltage signal.
